(19) United States
(12) Patent Application Publication
(10) Pub. No.: US 2013/0241376 A1
(43) Pub. Date: Sep. 19, 2013

(54) INERTIAL PLATFORM COMPRISING A HOUSING AND A SUSPENDED SENSOR ASSEMBLY

(71) Applicant: THALES, Neuilly-Sur-Seine (FR)

(72) Inventors: Jean-Rene Chevalier, Cenon Sur Vienne (FR); Thomas Lesage, Veigne (FR)

(73) Assignee: THALES, Neuilly-Sur-Seine (FR)

(21) Appl. No.: 13/792,775

(22) Filed: Mar. 11, 2013

(30) Foreign Application Priority Data
Mar. 15, 2012 (FR) 1200787

(51) Int. Cl. H05K 5/00

(52) U.S. Cl. CPC H05K 5/0078
USPC 312/223.1

(57) ABSTRACT

The invention pertains to an inertial platform comprising a housing and a suspended inertial sensor assembly (ECIS) furnished with rigidly inter-linked motion sensors, characterized in that it comprises:
a first internal suspension assembly inside the said sensor assembly, between a rigid mechanical support on which are mounted the said sensors and an intermediate mechanical piece, having small swing comprising a first number N₁, at least equal to four, of suspension pads mounted fixedly on the said suspended sensor assembly; and
a second external suspension assembly outside the said sensor assembly, between the said intermediate piece, forming part of the suspended assembly and the said housing, the said second external suspension assembly having large swing, comprising a second number N₂, at least equal to four, of suspension pads linked rigidly to the said housing, and not forming part of the suspended sensor assembly.

The present invention pertains to an inertial platform furnished with a housing and with a suspended sensor assembly, or suspended core, furnished with rigidly inter-linked motion sensors.

An inertial platform or inertial reference is understood in a very general manner to be:

a housing integrating electronic cards onboard which are embedded calculation and dialogue facilities; and

an assembly of rigidly inter-linked motion sensors such as accelerometric and/or magnetometric and/or gyrometric sensors generally referred to as inertial core or inertial sensor assembly.

In order to avoid disturbing the precision measurements performed by this inertial core, it is generally isolated mechanically from the housing by a suspension behaving in a mechanical environment as a low-pass filter for vibrations and/or shocks.

For obvious cost limitation reasons, it would be beneficial to develop an inertial sensor assembly or generic inertial core that is able to meet both civil and military needs.

Now, civil aeronautics requires low bulk and low mass, compatible moreover with the mechanical stresses applied to the hardware. Within this framework, it is necessary to develop a compact inertial core, with a suspension solution of limited cost, of limited bulk, and therefore of small swing.

Such a suspension is not compatible with military aeronautical applications, for which more significant swings are generally necessary.

Furthermore, the problem of the reuse of inertial cores is not solved and it is necessary to readapt the suspended inertial core for each new programme. Generally, the mechanics supporting the dampers must be tailored, this involving recalculating all or part of the balancing of the suspended inertial core, this operation possibly turning out to be relatively expensive.

Moreover, the introduction of sensors of electromechanical microsystem type, or MEMS standing for “microelectromechanical systems”, of high performance on a suspended inertial sensor assembly is rarely employed and requires a different filtering from that of the known inertial platforms.

Furthermore, the known inertial platforms exhibit symmetry defects. Indeed, in order to avoid gyrometric drift errors linked to coning motions and accelerometric bias errors linked to sculling motions (these terms being fairly widely used in publications in French), the centre of inertia and the elastic centre of the suspended inertial cores must be made to coincide as far as possible.

An aim of the invention is to alleviate the problems cited above.

In particular, an aim of the invention is to propose an inertial core adapted for different environments, such as civil and military.

There is proposed, according to one aspect of the invention, an inertial platform comprising a housing and a suspended inertial sensor assembly furnished with rigidly inter-linked motion sensors, characterized in that it comprises:

a first internal suspension assembly inside the said sensor assembly, between a rigid mechanical support on which are mounted the said sensors and an intermediate mechanical assembly, having small swing comprising a first number N₁, at least equal to four, of suspension pads mounted fixedly on the said suspended sensor assembly; and

a second external suspension assembly outside the said sensor assembly, between the said intermediate mechanical assembly, forming part of the suspended assembly and the said housing, the said second external suspension assembly having large swing, comprising a second number N₂, at least equal to four, of suspension pads linked rigidly to the said housing, and not forming part of the suspended sensor assembly.

Such an inertial platform is adapted for operating both in a civil environment and in a military environment, with low production cost overheads, but avoiding significant adaptation costs.

In one embodiment, the first number N₁ is equal to four, and the second number N₂ is equal to four.

Such an embodiment is optimal in terms of results with respect to complexity and to production cost.

According to one embodiment, the four suspension pads of the first internal suspension assembly are the vertices of a first pyramid, and the four suspension pads of the second external suspension assembly are the vertices of a second pyramid whose edges joining two distinct vertices are symmetric to the respective vertices of the first pyramid.

Such a geometry possesses a symmetry making it possible to avoid gyrometric drift errors linked to coning motions and accelerometric bias errors linked to sculling motions.

In one embodiment, the said intermediate mechanical assembly comprises two intermediate elements, such as crossbraces or the equivalent, adapted for rigidly linking together two suspension pads of the first internal suspension assembly and two suspension pads of the second external suspension assembly.

Thus, the part of the suspension external to the sensor assembly or core can be added very easily, without tailoring or dismantling the internal pads of the suspended core.

According to one embodiment, the two intermediate elements comprise respectively a crossbrace, for example identical, or, stated otherwise, a cross-shaped reinforcing piece.

Such an embodiment is convenient and of reduced cost.

For example, the two intermediate elements are adapted for receiving additional sensors.

Thus, the mechanical pieces added between the suspensions can support measurement sensors (acceleration, temperatures, etc.) making it possible, if appropriate, to activate or to participate in the processing of the information delivered by the inertial core.

In one embodiment, the said suspension pads have symmetry of revolution.

Thus, for each pad it is possible to distinguish axial and radial (linear and angular) stiffnesses which can, subsequently, be associated or compensated according to the orientation of the pads.

According to one embodiment, the pads are disposed so that the axes of revolution of the four pads of the first internal suspension assembly are parallel to one another in a first direction, the axes of revolution of the four pads of the second external suspension assembly are parallel to one another in a second direction, the said first and second directions being perpendicular.

Thus, it is possible to make the pads work in two directions according to their radial mode, and in the third direction according to the axial mode.

As a variant, according to another embodiment, the pads are disposed so that the axes of revolution of the pads pass through the centre of inertia of the suspended inertial sensor assembly.

Thus, optimizations can be effected with respect to the modes obtained.

In another embodiment, the axes of revolution of two distinct pads form an angle of between 0 and 90 degrees.

According to one embodiment, the said motion sensors comprise at least one electromechanical microsystem.

Thus, the second external suspension assembly is particularly well adapted for guaranteeing sufficient filtering for MEMSs.

The invention will be better understood on studying a few embodiments described by way of wholly non-limiting examples and illustrated by the appended drawings in which:

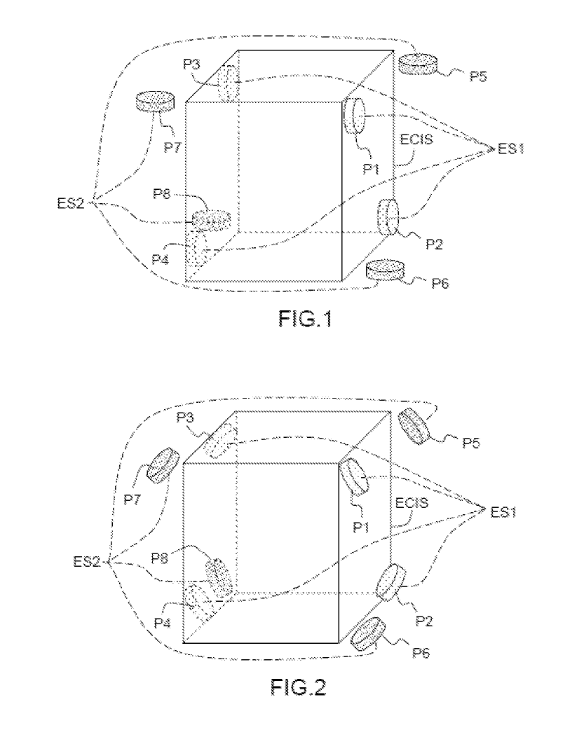

FIG. 1 schematically illustrates an inertial platform furnished with two suspension assemblies, according to one aspect of the invention;

FIG. 2 schematically illustrates an inertial platform furnished with two suspension assemblies, according to another aspect of the invention;

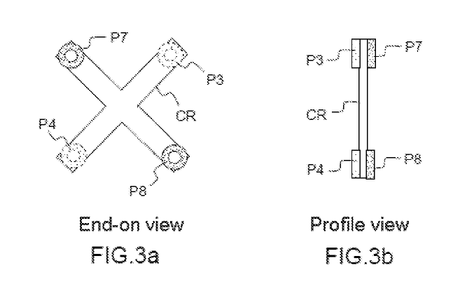

FIGS. 3a and 3b illustrate an exemplary embodiment of intermediate elements adapted for rigidly linking together two suspension pads of the first internal suspension assembly and two suspension pads of the second external suspension assembly, according to one aspect of the invention.

As illustrated in FIG. 1, a suspended inertial sensor assembly ECIS or inertial core of an inertial platform comprises a first suspension assembly ES1 internal to the sensor assembly, between the rigid mechanical support on which are mounted these sensors and an intermediate mechanical assembly, having small swing comprising a first number N₁ at least equal to four, of suspension pads mounted fixedly on the said suspended sensor assembly, and a second external suspension assembly ES2 external to the sensor assembly, between the intermediate mechanical assembly, forming part of the suspended assembly and the housing, having large swing comprising a second number N₂, at least equal to four, of suspension pads linked rigidly to the said housing.

The concepts of large swing and small swing are relative, and typically of the order of a mm for the suspension internal to the sensor assembly and some ten mm for the external suspension.

In FIGS. 1 and 2, the Rigid Mechanical Support on which are Mounted the Sensors and the Intermediate Mechanical Assembly are not Represented.

In this instance, in the example of FIG. 1 are represented a first internal suspension assembly ES1 comprising four suspension pads P1, P2, P3 and P4, i.e. N₁=4, and a second external suspension assembly ES2 comprising four suspension pads P5, P6, P7 and P8, i.e. N₂=4.

In the example of FIG. 1, the four suspension pads P1, P2, P3 and P4 of the first internal suspension assembly ES1 are the vertices of a first pyramid, and the four suspension pads P5, P6, P7 and P8 of the second external suspension assembly ES2 are the vertices of a second pyramid whose edges joining two distinct vertices are symmetric to the respective vertices of the first pyramid.

A suspension of “pyramid” type can be defined by the position of the four suspension pads with respect to one another. If the elastic centre of the assembly of four pads is taken as origin, and if dx, dy and dz denote three distances along three right-handed orthogonal axes whose intersection lies at the elastic centre of the suspended assembly, the position of the four pads is given by: (dx, −dy, −dz); (−dx, −dy, dz); (−dx, dy, −dz); and (dx, dy, dz).

In this example, the assembly of the pads P1, P2, P3, P4, P5, P6, P7 and P8 of the two suspension assemblies ES1 and ES2 are suspension pads having symmetry of revolution and disposed so that the axes of revolution of the four pads P1, P2, P3, and P4 of the first internal suspension assembly ES1 are parallel to one another in a first direction, the axes of revolution of the four pads P5, P6, P7 and P8 of the second external suspension assembly ES2 are parallel to one another in a second direction, and the said first and second directions are perpendicular.

This embodiment makes it possible to compensate the axial and radial characteristics of the suspensions internal and external to the core.

As a variant, as illustrated in FIG. 2, the pads are disposed so that the axes of revolution of the pads all pass through the centre of inertia of the suspended inertial sensor assembly ECIS.

This embodiment makes it possible to minimize the gyrometric drift errors linked to coning motions and the accelerometric bias errors linked to sculling motions.

In a more general manner, the axes of revolution of two distinct pads can form an angle of between 0 and 90 degrees.

These exemplary embodiments in which each internal and external suspension assembly ES1, ES2 comprises four suspension pads exhibits a particular cost/result ratio benefit.

An inertial platform according to one aspect of the invention can comprise two intermediate elements adapted for rigidly linking together two suspension pads of the first internal suspension assembly and two suspension pads of the second external suspension assembly.

FIGS. 3a and 3b schematically represent an exemplary embodiment of such intermediate elements, in this instance embodied in the form of crossbraces CR.

The Crossbraces CR are an Exemplary Embodiment of the Intermediate Mechanical Assembly.

FIG. 3a represents an end-on view and FIG. 3b a side view of such a crossbrace CR linking rigidly for example the pads P3 and P4 of the first suspension assembly ES1 and the pads P7 and P8 of the second suspension assembly ES2.

The intermediate elements can be identical and adapted for receiving additional sensors (acceleration, temperatures, etc.) making it possible to activate or to participate in the processing of the information delivered by the suspended inertial sensor assembly ECIS.

The suspended inertial sensor assembly ECIS can comprise at least one electromechanical microsystem or MEMS, in which case the dual suspension according to the invention is particularly well adapted for effective filtering of the exterior disturbances (vibrations, shocks), which, thus, no longer disturb the suspended inertial core ECIS.

1. Inertial platform comprising a housing and a suspended inertial sensor assembly (ECIS) furnished with rigidly inter-linked motion sensors, characterized in that it comprises:
a first internal suspension assembly (ES1) inside the said sensor assembly, between a rigid mechanical support on which are mounted the said sensors and an intermediate mechanical assembly, having small swing comprising a first number N₁, at least equal to four, of suspension pads (P1, P2, P3, P4) mounted fixedly on the said suspended sensor assembly (ECIS); and
a second external suspension assembly (ES2) outside the said sensor assembly, between the said intermediate mechanical assembly, forming part of the suspended assembly and the said housing, the said second external suspension assembly having large swing, comprising a second number N₂, at least equal to four, of suspension pads (P5, P6, P7, P8) linked rigidly to the said housing, and not forming part of the suspended sensor assembly.

2. Inertial platform according to claim 1, in which the first number N₁ is equal to four, and the second number N₂ is equal to four.

3. Inertial platform according to claim 2, in which the four suspension pads (P1, P2, P3, P4) of the first internal suspension assembly (ES1) are the vertices of a first pyramid, and the four suspension pads (P5, P6, P7, P8) of the second external suspension assembly (ES2) are the vertices of a second pyramid whose edges joining two distinct vertices are symmetric to the respective vertices of the first pyramid.

4. Inertial platform according to claim 3, in which the said intermediate mechanical assembly comprises two intermediate elements adapted for rigidly linking together two suspension pads (P3, P4) of the first internal suspension assembly (ES1) and two suspension pads (P7, P8) of the second external suspension assembly (ES2).

5. Inertial platform according to claim 4, in which the two intermediate elements comprise respectively a crossbrace (CR).

6. Inertial platform according to claim 4, in which the two intermediate elements are adapted for receiving additional sensors.

7. Inertial platform according to claim 1, in which the said suspension pads (P1, P2, P3, P4, P5, P6, P7, P8) have symmetry of revolution.

8. Inertial platform according to claim 7, in which the pads are disposed so that the axes of revolution of the four pads (P1, P2, P3, P4) of the first internal suspension assembly (ES1) are parallel to one another in a first direction, the axes of revolution of the four pads (P5, P6, P7, P8) of the second external suspension assembly (ES2) are parallel to one another in a second direction, the said first and second directions being perpendicular.

9. Inertial platform according to claim 7, in which the suspension pads (P1, P2, P3, P4, P5, P6, P7, P8) are disposed so that the axes of revolution of the pads (P1, P2, P3, P4, P5, P6, P7, P8) pass through the centre of inertia of the suspended inertial sensor assembly (ECIS).

10. Inertial platform according to claim 7, in which the axes of revolution of two distinct pads form an angle of between 0 and 90 degrees.

11. Inertial platform according to claim 1, in which the said motion sensors comprise at least one electromechanical microsystem (MEMS).

12. Inertial platform according to claim 2, in which the said suspension pads (P1, P2, P3, P4, P5, P6, P7, P8) have symmetry of revolution.

13. Inertial platform according to claim 3, in which the said suspension pads (P1, P2, P3, P4, P5, P6, P7, P8) have symmetry of revolution.

14. Inertial platform according to claim 13, in which the pads are disposed so that the axes of revolution of the four pads (P1, P2, P3, P4) of the first internal suspension assembly (ES1) are parallel to one another in a first direction, the axes of revolution of the four pads (P5, P6, P7, P8) of the second external suspension assembly (ES2) are parallel to one another in a second direction, the said first and second directions being perpendicular.

15. Inertial platform according to claim 13, in which the suspension pads (P1, P2, P3, P4, P5, P6, P7, P8) are disposed so that the axes of revolution of the pads (P1, P2, P3, P4, P5, P6, P7, P8) pass through the centre of inertia of the suspended inertial sensor assembly (ECIS).

16. Inertial platform according to claim 13, in which the axes of revolution of two distinct pads form an angle of between 0 and 90 degrees.

17. Inertial platform according to claim 4, in which the said suspension pads (P1, P2, P3, P4, P5, P6, P7, P8) have symmetry of revolution.

18. Inertial platform according to claim 17, in which the pads are disposed so that the axes of revolution of the four pads (P1, P2, P3, P4) of the first internal suspension assembly (ES1) are parallel to one another in a first direction, the axes of revolution of the four pads (P5, P6, P7, P8) of the second external suspension assembly (ES2) are parallel to one another in a second direction, the said first and second directions being perpendicular.

19. Inertial platform according to claim 17, in which the suspension pads (P1, P2, P3, P4, P5, P6, P7, P8) are disposed so that the axes of revolution of the pads (P1, P2, P3, P4, P5, P6, P7, P8) pass through the centre of inertia of the suspended inertial sensor assembly (ECIS).

20. Inertial platform according to claim 17, in which the axes of revolution of two distinct pads form an angle of between 0 and 90 degrees.
